(19) United States
(12) Patent Application Publication
(10) Pub. No.: US 2025/0311549 A1
(43) Pub. Date: Oct. 2, 2025

(54) DISPLAY DEVICE

(71) Applicant: Samsung Display Co., LTD., Yongin-si (KR)

(72) Inventors: Sun Kwun SON, Yongin-si (KR); Na Hyeon CHA, Yongin-si (KR)

(21) Appl. No.: 19/030,609

(22) Filed: Jan. 17, 2025

(30) Foreign Application Priority Data
Mar. 29, 2024 (KR) 10-2024-0043475

(51) Int. Cl. H10K 59/121; G09G 3/3233; H10K 59/131

(52) U.S. Cl. CPC H10K 59/1213; G09G 3/3233; H10K 59/1216; H10K 59/131; G09G 2300/0426; G09G 2300/0819; G09G 2300/0852; G09G 2330/021

(57) ABSTRACT

A display device includes: a first pixel in a first row and a first column; and a second pixel in a second row next to the first row and in the first column, wherein each of the first and second pixels includes: a light-emitting element on a substrate; a first transistor configured to supply a driving current to a second node which is connected to a first electrode of the light-emitting element, based on a voltage of a first node which is connected to a gate electrode of the first transistor; a second transistor connected to the first node; and a third transistor connected between a third node which is connected to a drain electrode of the second transistor and the second node, and wherein the third node of the first pixel and the third node of the second pixel are directly connected with each other.

### CROSS-REFERENCE TO RELATED APPLICATION

The present application claims priority to and the benefit of Korean Patent Application No. 10-2024-0043475, filed on Mar. 29, 2024, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

As the information-oriented society evolves, consumer demand for display devices is ever increasing. For example, display devices are being employed by a variety of electronic devices such as smart phones, digital cameras, laptop computers, navigation devices, and smart televisions. Display devices may be flat panel display devices such as liquid-crystal display devices, field emission display devices, and organic light-emitting display devices. Among such flat panel display devices, a light-emitting display device includes a light-emitting element that can emit light on its own, so that each of the pixels of the display panel can emit light by themselves. Accordingly, a light-emitting display device can display images without a backlight unit that supplies light to the display panel.

The above information disclosed in this Background section is only for enhancement of understanding of the background and therefore the information discussed in this Background section does not necessarily constitute prior art.

### SUMMARY

Aspects of some embodiments of the present disclosure include a display device that can achieve relatively high resolution and relatively reduce power consumption.

However, the characteristics of embodiments of the present disclosure are not limited to those set forth herein. The above and other characteristics of embodiments of the present disclosure will become more apparent to one of ordinary skill in the art to which the present disclosure pertains by referencing the detailed description of the present disclosure given below.

According to some embodiments of the present disclosure, a display device includes a first pixel in a first row and a first column, and a second pixel in a second row next to the first row and in the first column. According to some embodiments, each of the first and second pixels includes a light-emitting element on a substrate, a first transistor configured to supply a driving current to a second node which is connected to a first electrode of the light-emitting element, based on a voltage of a first node which is connected to a gate electrode of the first transistor, a second transistor connected to the first node, and a third transistor connected between a third node which is connected to a drain electrode of the second transistor and the second node. According to some embodiments, the third node of the first pixel and the third node of the second pixel are directly connected with each other.

According to some embodiments, the display device may further include an initialization voltage line supplying an initialization voltage; and a data line supplying a data voltage. According to some embodiments, each of the first and second pixels may include a first capacitor connected between the first node and the initialization voltage line, and a second capacitor connected between the third node and the data line.

According to some embodiments, a first electrode of the second capacitor of the first pixel and a first electrode of the second capacitor of the second pixel may be formed integrally.

According to some embodiments, the drain electrode of the second transistor of the first pixel and the drain electrode of the second transistor of the second pixel may be formed integrally.

According to some embodiments, each of the first and second pixels may include an active layer on the substrate and including a semiconductor region of each of the first to third transistors, a first gate layer on the active layer and comprising a first electrode of the first capacitor, a second gate layer on the first gate layer and comprising a second electrode of the first capacitor, a first source metal layer on the second gate layer and comprising a capacitor electrode which is connected to the first electrode of the second capacitor, and a second source metal layer on the first source metal layer and comprising the data line which is connected to the second electrode of the second capacitor.

According to some embodiments, a capacitor electrode of the first pixel and the capacitor electrode of the second pixel may be formed integrally.

According to some embodiments, a first portion of the initialization voltage line may be in the second gate layer and extends in a first direction, and a second portion of the initialization voltage line may be in a third source metal layer on the second source metal layer and may extend in a second direction intersecting the first direction.

According to some embodiments, the display device may further include a third pixel in the first row and a second column next to the first column, and a fourth pixel in the second row and in the second column. According to some embodiments, each of the third and fourth pixels may include a light-emitting element on a substrate, a first transistor configured to supply a driving current to a second node which is connected to a first electrode of the light-emitting element, based on a voltage of a first node which is connected to a gate electrode, a second transistor connected to the first node, and a third transistor connected between a third node which is connected to a drain electrode of the second transistor and the second node. The third node of the third pixel and the third node of the fourth pixel may be directly connected with each other.

According to some embodiments, a source electrode of the first transistor of the first pixel and a source electrode of the first transistor of the third pixel may be formed integrally.

According to some embodiments, each of the first and second pixels may include an active layer on the substrate, a first gate layer on the active layer, a second gate layer on the first gate layer, a first source metal layer on the second gate layer, a second source metal layer on the first source metal layer, and a third source metal layer comprising a driving voltage line on the second source metal layer. According to some embodiments, a source electrode of the first transistor of the first pixel and a source electrode of the first transistor of the third pixel share a single driving voltage line.

According to some embodiments of the present disclosure, a display device includes a first pixel in a first row and a first column, a second pixel in a second row next to the first row and the first column, an initialization voltage line supplying an initialization voltage, and a data line supplying a data voltage. According to some embodiments, each of the first and second pixels includes a light-emitting element on a substrate, a first transistor configured to supply a driving current to a second node which is connected to a first electrode of the light-emitting element, based on a voltage of a first node which is connected to a gate electrode, a first capacitor connected between the first node and the initialization voltage line, a second transistor connected to the first node, a second capacitor connected between the data line and a third node which is connected to a drain electrode of the second transistor, and a third transistor electrically connecting the third node with the second node. According to some embodiments, a first electrode of the second capacitor of the first pixel and a first electrode of the second capacitor of the second pixel are formed integrally.

According to some embodiments, the display device may further include a first scan write line supplying a first scan write signal to the second transistor of the first pixel, a second scan write line supplying a second scan write signal to the second transistor of the second pixel, and a scan control line supplying a scan control signal to the third transistor of the first pixel and the third transistor of the second pixel.

According to some embodiments, each of the first and second pixels may include an active layer on the substrate, a first gate layer on the active layer and comprising a first electrode of the first capacitor, a second gate layer on the first gate layer and comprising a second electrode of the first capacitor, a first source metal layer on the second gate layer and comprising a capacitor electrode which is connected to the first electrode of the second capacitor, and a second source metal layer on the first source metal layer and comprising the data line which is connected to the second electrode of the second capacitor.

According to some embodiments, each of the first and second pixels may further include a third gate layer between the second gate layer and the first source metal layer. According to some embodiments, a third electrode of the first capacitor may be in the third gate layer and connected to the first electrode of the first capacitor.

According to some embodiments, the third electrode of the first capacitor may electrically connect the first electrode of the first capacitor with a source electrode of the second transistor.

According to some embodiments, the active layer of the first pixel and the active layer of the second pixel may be symmetrical with respect to a boundary line between the first pixel and the second pixel.

According to some embodiments, a first portion of the initialization voltage line may be in the second gate layer and extends in a first direction, and a second portion of the initialization voltage line may be in a third source metal layer on the second source metal layer and may extend in a second direction intersecting the first direction.

According to some embodiments, the first portion of the initialization voltage line may include the second electrode of the first capacitor.

According to some embodiments, the display device may further include a third pixel in the first row and a second column next to the first column, and a fourth pixel in the second row and the second column. According to some embodiments, each of the third and fourth pixels may include an active layer on the substrate and comprising a semiconductor region of each of the first to third transistors, a first gate layer on the active layer and comprising a first electrode of the first capacitor, a second gate layer on the first gate layer and comprising a second electrode of the first capacitor, a first source metal layer on the second gate layer and comprising a capacitor electrode which is connected to the first electrode of the second capacitor, and a second source metal layer on the first source metal layer and comprising the data line which is connected to the second electrode of the second capacitor. According to some embodiments, the active layer of the first pixel and the active layer of the third pixel may be symmetrical with respect to a boundary line between the first pixel and the third pixel.

According to some embodiments, each of the third and fourth pixels may include a light-emitting element on a substrate, a first transistor configured to supply a driving current to a second node which is connected to a first electrode of the light-emitting element, based on a voltage of a first node which is connected to a gate electrode, a second transistor connected to the first node, and a third transistor connected between a third node which is connected to the drain electrode of the second transistor and the second node. According to some embodiments, a source electrode of the first transistor of the first pixel and a source electrode of the first transistor of the third pixel may share a single driving voltage line.

According to some embodiments of the present disclosure, a high-resolution display device can be implemented by relatively reducing the area of the pixel circuit by relatively reducing the numbers of lines and contact holes, and the power consumption can be relatively reduced by relatively increasing the area of a capacitor as a capacitor electrode is shared by adjacent pixels.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a view showing a virtual reality device including a display device according to some embodiments.

FIGS. 2 and 3 are views showing a head-mounted display device including a display device according to some embodiments.

FIG. 4 is a circuit diagram showing pixels of a display device according to some embodiments of the present disclosure.

FIG. 5 is a view showing a layout of pixels in a display device according to some embodiments of the present disclosure.

FIG. 6 is a view showing some layers of the view of FIG. 5.

FIG. 7 is a view showing some other layers of the view of FIG. 5.

FIG. 8 is a view showing a layout of one of the pixels of FIG. 5.

FIG. 9 is a view showing some layers of the view of FIG. 8.

FIG. 10 is a view showing some other layers of the view of FIG. 8.

FIG. 11 is a cross-sectional view showing a pixel in a display device according to some embodiments of the present disclosure.

### DETAILED DESCRIPTION

Aspects and features of some embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

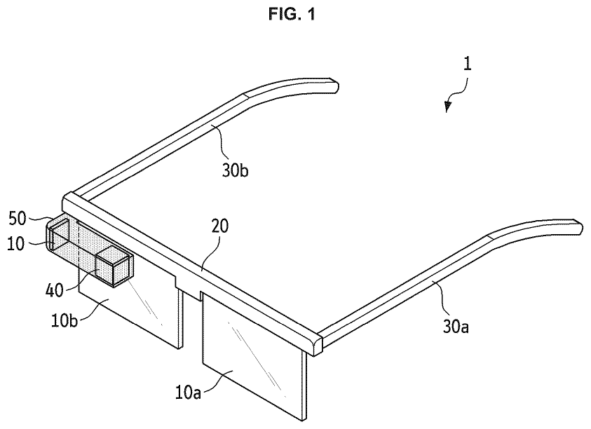

FIG. 1 is a view showing a virtual reality device including a display device according to some embodiments.

Referring to FIG. 1, a virtual reality device 1 may be a glasses-type device. The virtual reality device 1 may include the display device 10, a left eye lens 10a, a right eye lens 10b, a support frame 20, eyeglass temples 30a and 30b, a reflective member 40, and a display device case 50.

Optionally, the virtual reality device 1 may be applied to a head-mounted display (HMD) including a band that can be worn on the head instead of the temples 30a and 30b. Accordingly, it is to be understood that the virtual reality device 1 is not limited to that shown in FIG. 1 but may be applied in a variety of electronic devices in a variety of forms.

The display device case 50 may include the display device 10 and the reflective member 40. An image displayed on the display device 10 may be reflected by the reflective member 40 and provided to the user's right eye through the right eye lens 10b. Accordingly, the user may watch a virtual reality image displayed on the display device 10 through the right eye.

Although the display device case 50 may be located at the right end of the support frame 20, the position of the case 50 is not limited thereto. For another example, the display device case 50 may be located at the left end of the support frame 20. In such case, images displayed on the display device 10 may be reflected by the reflective member 40 and provided to the user's left eye through the left eye lens 10a. Accordingly, the user may watch virtual reality images displayed on the display device 10 through the left eye.

For another example, the display device cases 50 may be located at both the left and right ends of the support frame 20, respectively. In such case, the user can watch a virtual reality image displayed on the display device 10 through both the left and right eyes.

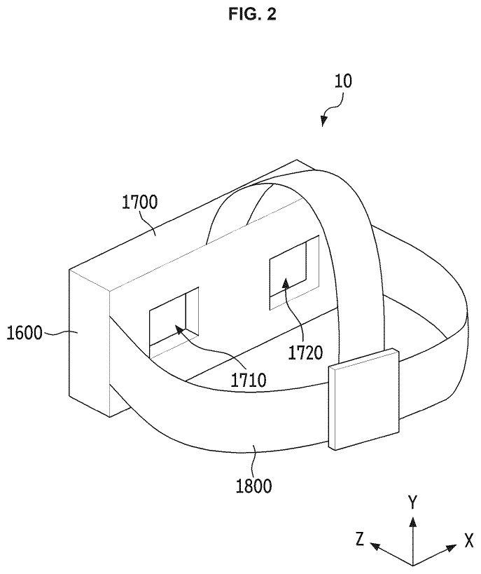

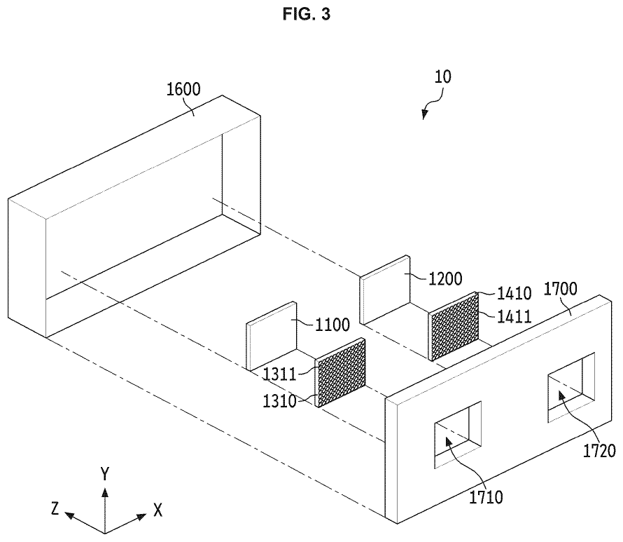

FIGS. 2 and 3 are views showing a head-mounted display device including a display device according to some embodiments.

Referring to FIGS. 2 and 3, a display device 10 may be applied to a head-mounted display (HMD). A first display device 1100 may provide images to the user's right eye, and a second display device 1200 may provide images to the user's left eye.

A first lens array 1310 may be located between the first display device 1100 and a housing cover 1700. The first lens array 1310 may include a plurality of lenses 1311. The plurality of lenses 1311 may include convex lenses that are convex toward the housing cover 1700.

A second lens array 1410 may be located between the second display device 1200 and the housing cover 1700. The second lens array 1410 may include a plurality of lenses 1411. The plurality of lenses 1411 may include convex lenses that are convex toward the housing cover 1700.

A display panel housing 1600 may accommodate the first display device 1100, the second display device 1200, the first lens array 1310 and the second lens array 1410. One face of the display panel housing 1600 may be opened for accommodating the first display device 1100, the second display device 1200, the first lens array 1310 and the second lens array 1410.

The housing cover 1700 may cover the opened surface of the housing 1600. The housing cover 1700 may include a first opening 1710 where the user's left eye is located and a second opening 1720 where the user's right eye is located. For example, the first opening 1710 and the second opening 1720 may be formed in a rectangular shape, but the shapes of the first and second openings 1710 and 1720 are not limited thereto. For another example, the first opening 1710 and the second opening 1720 may be formed in a circular shape or an elliptical shape. For another example, the first and second openings 1710 and 1720 may be integrated to form a single opening.

The first opening 1710 may be aligned with the first display device 1100 and the first lens array 1310, and the second opening 1720 may be aligned with the second display device 1200 and the second lens array 1410. Therefore, a user may see virtual images of images on the first display device 1100 magnified by the first lens array 1310 through the first opening 1710, and virtual images of images on the second display device 1200 magnified by the second lens array 1410 through the second opening 1720.

A head strap band 1800 may fix the housing 1600 to the user's head so that the first opening 1710 and the second opening 1720 of the housing cover 1700 are in line with the user's left and right eyes, respectively. The head strap band 1800 may be connected to the top, left and right sides of the housing 1600.

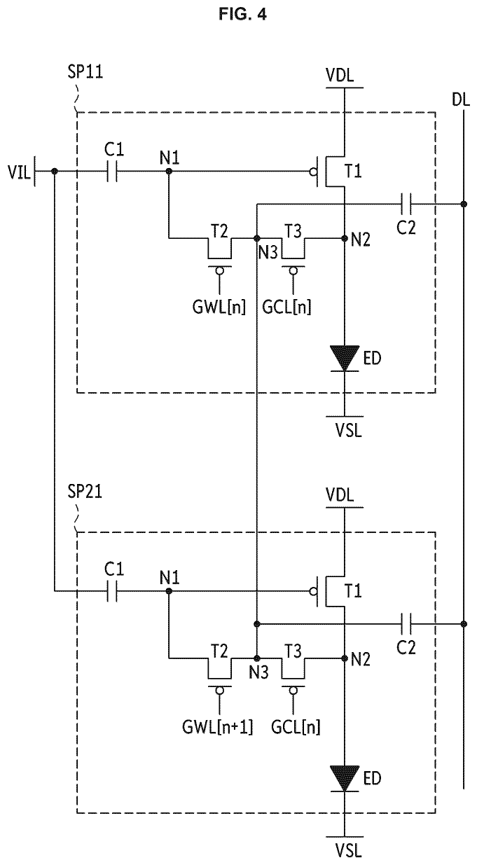

FIG. 4 is a circuit diagram showing pixels of a display device according to some embodiments of the present disclosure. Although FIG. 4 illustrates various components in a pixel circuit according to some embodiments, embodiments according to the present disclosure are not limited thereto, and according to some embodiments, the pixel circuit may include additional components or fewer components without departing from the spirit and scope of embodiments according to the present disclosure.

Referring to FIG. 4, the display device 10 of FIG. 1 or the display device 10 of FIG. 2 may include an 11^{th}, pixel SP11 and a 21^{st} pixel SP21. For another example, the 11^{th}, pixel SP11 and the 21^{st} pixel SP21 may be employed by portable electronic devices such as a mobile phone, a smart phone, a tablet PC, a mobile communications terminal, an electronic notebook, an electronic book, a portable multimedia player (PMP), a navigation device and a ultra mobile PC (UMPC). For yet another example, the 11th pixel SP11 and the 21st pixel SP21 may be applied as a display unit of a television, a laptop computer, a monitor, an electronic billboard, a smart watch, a watch phone, or Internet of Things (IoT).

The 11^{th} pixel SP11 and the 21^{st} pixel SP21 may be arranged in different rows. The 21^{st} pixel SP21 may be located in the row next to the 11^{th} pixel SP11. The 11^{th} pixel SP11 may be connected to the n^{th} scan write line GWL[n], and the 21^{st} pixel SP21 may be connected to the (n+1)^{th} scan write line GWL[n+1], where n is a positive integer. Each of the 11^{th} pixel SP11 and the 21^{st} pixel SP21 may be connected to the n^{th} scan control line GCL[n], a data line DL, an initialization voltage line VIL, a driving voltage line VDL, and a low-level voltage line VSL.

Each of the 11^{th} pixel SP11 and the 21^{st} pixel SP21 may include a light-emitting element ED and a pixel circuit for driving the light-emitting element ED. The pixel circuit may include first to third transistors T1, T2 and T3, and first and second capacitors C1 and C2.

The first transistor T1 may supply a driving current to the light-emitting element ED. The first transistor T1 may include a gate electrode, a source electrode, and a drain electrode. The gate electrode of the first transistor T1 may be connected to a first node N1, the source electrode thereof may be connected to the driving voltage line VDL, and the drain electrode thereof may be connected to a second node N2 which is connected to a first electrode of the light-emitting element ED. The first transistor T1 may control the source-drain current Isd (hereinafter, referred to as “driving current”) according to the data voltage applied to the gate electrode. The driving current Isd flowing through the channel of the first transistor T1 may be proportional to the square of the difference between the threshold voltage Vth and the voltage Vsg between the source electrode and the gate electrode of the first transistor T1 (Isd=k′×(Vsg−Vth)²), where k denotes a proportional coefficient determined by the structure and physical properties of the first transistor T1, Vsg denotes the source-gate voltage of the first transistor T1, and Vth denotes the threshold voltage of the first transistor T1.

The light-emitting element ED may receive the driving current Isd to emit light. The amount or the luminance of the light emitted from the light-emitting element ED may be proportional to the magnitude of the driving current Isd. The light-emitting element ED may include a first electrode, a second electrode, and an emissive layer located between the first electrode and the second electrode. The first electrode of the light-emitting element ED may be connected to a second node N2. The first electrode of the light-emitting element ED may be electrically connected to the drain electrode of the first transistor T1 and the drain electrode of the third transistor T3 through the second node N2. The second electrode of the light-emitting element ED may be connected to the low-level voltage line VSL to receive a low-level voltage from it. For example, the first electrode of the light-emitting element ED may be an anode electrode or a pixel electrode, while the second electrode thereof may be a cathode electrode or a common electrode. It is, however, to be understood that the present disclosure is not limited thereto.

The second transistor T2 of the 11^{th} pixel SP11 may be turned on by the n^{th} scan signal of the n^{th} scan write line GWL[n] to electrically connect the first node N1 with a third node N3. A gate electrode of the second transistor T2 of the 11^{th} pixel SP11 may be connected to the n^{th} scan line GWL[n], a source electrode thereof may be connected to the first node N1, and a drain electrode source thereof may be connected to the third node N3. The second transistor T2 of the 21st pixel SP21 may be turned on by the (n+1)^{th} scan write signal of the (n+1)^{th} scan write line GWL[n+1] to electrically connect the first node N1 with the third node N3. A gate electrode of the second transistor T2 of the 21^{st} pixel SP21 may be connected to the (n+1)^{th} scan write line GWL[n+1], a source electrode thereof may be connected to the first node N1, and a drain electrode source thereof may be connected to the third node N3. The first node N1 may be electrically connected to the first electrode of the first capacitor C1, and the voltage of the first node N1 may be initialized by the initialization voltage line VIL connected to the second electrode of the first capacitor C1. The third node N3 may be electrically connected to a first electrode of the second capacitor C2, and the voltage of the third node N3 may be changed to a voltage equal to the data voltage by the data line DL connected to a second electrode of the second capacitor C2.

The third transistor T3 of each of the 11^{th} pixel SP11 and the 21^{st} pixel SP21 may be turned on by the n^{th} scan control signal of the n^{th} scan control line GCL[n] to electrically connect the third node N3 with the second node N2. The n^{th} scan control line GCL[n] connected to the 11^{th} pixel SP11 and the n^{th} scan control line GCL[n] connected to the 21st pixel SP21 may be electrically connected with each other in a pixel area, a display area or a non-display area. A gate electrode of the third transistor T3 may be connected to the n^{th} scan line GWL[n], a source electrode thereof may be connected to the third node N3, and a drain electrode source thereof may be connected to the second node N2.

Each of the first to third transistors T1, T2 and T3 may include a silicon-based active layer. For example, each of the first to third transistors T1, T2 and T3 may include an active layer made of low-temperature polycrystalline silicon (LTPS). The active layer made of low-temperature polycrystalline silicon may have a high electron mobility and excellent turn-on characteristics. Accordingly, as the display device 10 includes transistors having excellent turn-on characteristics, the plurality of pixels SP can be driven stably and efficiently.

The first to third transistors T1, T2 and T3 may be p-type transistors. For example, each of the first to third transistors T1, T2 and T3 may output a current flowing into the drain electrode to the drain electrode in response to a gate-low voltage applied to the gate electrode.

For another example, at least one of the first to third transistors T1, T2 or T3 may include an oxide-based active layer. A transistor including an oxide-based active layer may have a coplanar structure in which a gate electrode is located at the top. A transistor including an oxide-based active layer may be an n-type transistor and may output current introduced into the drain electrode via the source electrode based on a gate-high voltage applied to the gate electrode.

The first capacitor C1 may be connected between the first node N1 which is the gate electrode of the first transistor T1 and the initialization voltage line VIL. For example, the first electrode of the first capacitor C1 may be connected to the first node N1, the second electrode of the first capacitor C1 may be connected to the initialization voltage line VIL, such that the potential difference between the gate electrode of the first transistor T1 and the initialization voltage line VIL can be held. Accordingly, the voltage of the first node N1 may be initialized by the initialization voltage line VIL.

The second capacitor C2 may be connected between the third node N3 and the second node N2. For example, the first electrode of the second capacitor C2 may be connected to the third node N3, the second electrode of the second capacitor C2 may be connected to the data line DL, such that the potential difference between the third node N3 and the data line DL can be maintained. Accordingly, the voltage of the third node N3 may be changed to a voltage equal to the data voltage by the data line DL.

The third node N3 of the 11^{th} pixel SP11 and the third node N3 of the 21^{st} pixel SP21 may be directly connected with each other. The first electrode of the second capacitor C2 of the 11^{th}, pixel SP11 and the first electrode of the second capacitor C2 of the 21^{st} pixel SP21 may be formed integrally. Accordingly, the high-resolution display device 10 can be implemented by relatively reducing the area of the pixel circuit by relatively reducing the numbers of lines and contact holes, and the power consumption can be relatively reduced by increasing the area of the second capacitor C2.

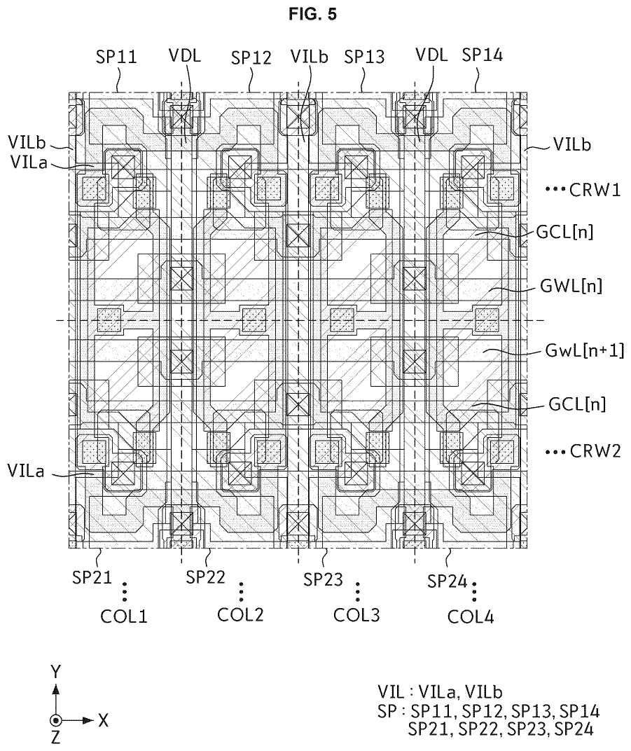

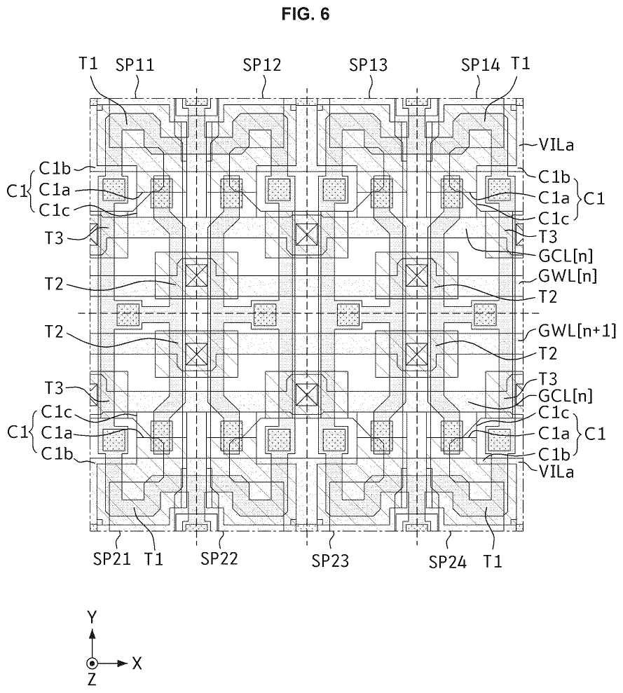

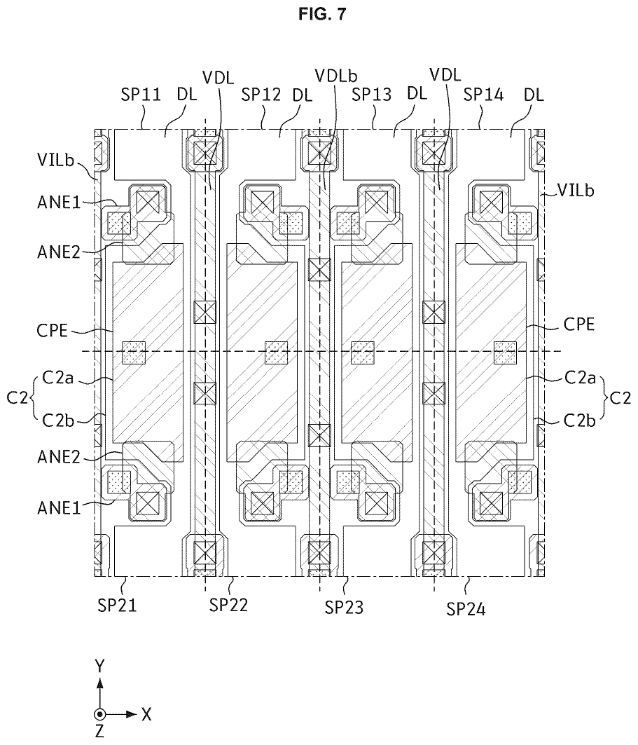

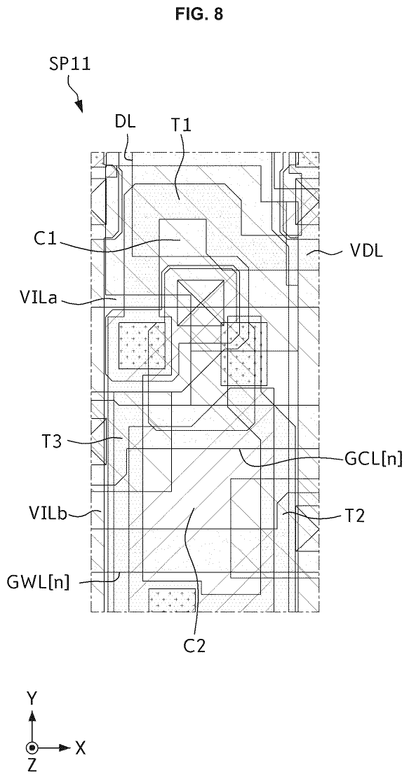

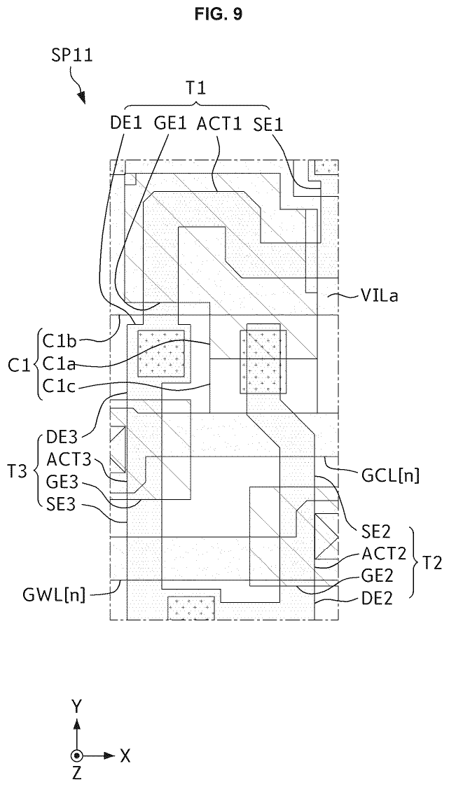

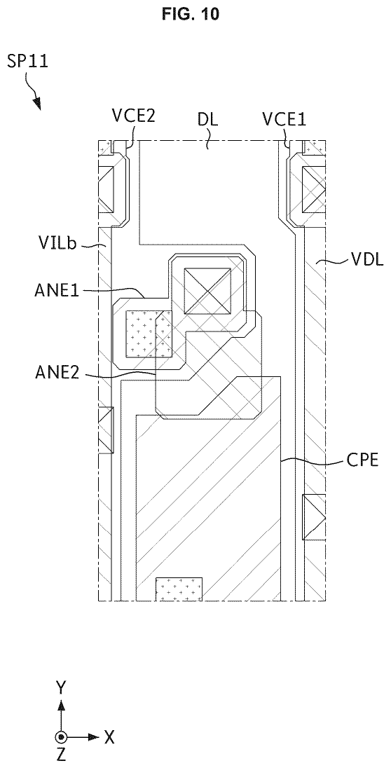

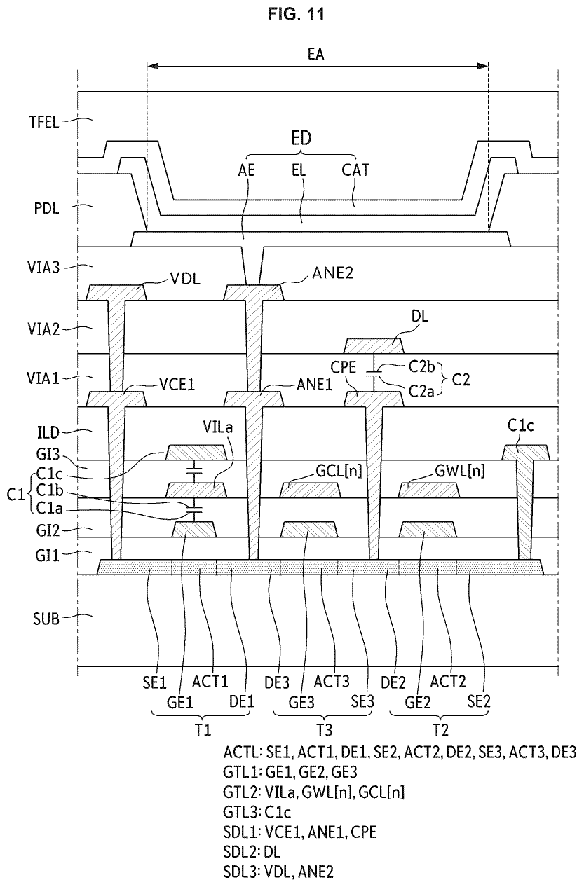

FIG. 5 is a view showing a layout of pixels in a display device according to some embodiments of the present disclosure. FIG. 6 is a view showing some layers of the view of FIG. 5, for example, showing a stacked structure of an active layer ACTL, first to third gate layers GTL1, GTL2 and GTL3. FIG. 7 is a view showing some other layers of the view of FIG. 5, for example, showing a stacked structure of first to third source metal layer SDL1, SDL2 and SDL3. FIG. 8 is a view showing a layout of some pixels of the view of FIG. 5, and is an enlarged view of a 22^{nd} pixel SP22. FIG. 9 is a view showing some layers of the view of FIG. 8, for example, showing a stacked structure of an active layer ACTL, first to third gate layers GTL1, GTL2 and GTL3. FIG. 10 is a view showing some other layers of the view of FIG. 8, for example, showing a stacked structure of first to third source metal layer SDL1, SDL2 and SDL3. FIG. 11 is a cross-sectional view showing a pixel in a display device according to some embodiments of the present disclosure.

Referring to FIGS. 5 to 11, the pixels SP may be arranged in rows and columns. For example, the pixels SP may be arranged along first and second rows CRW1 and CRW2 and first to fourth columns COL1, COL2, COL3 and COL4. A 11^{th} pixel SP11, a 12^{th} pixel SP12, a 13^{th} pixel SP13 and a 14^{th} pixel SP14 may be located in the first row CRW1, and may be electrically connected to the n^{th} scan write line GWL[n] and the n^{th} scan control line GCL[n]. A 21^{st} pixel SP21, a 22^{nd} pixel SP22, a 23^{rd} pixel SP23 and a 24^{th} pixel SP24 may be located in the second row CRW2, and may be electrically connected to the (n+1)^{th} scan write line GWL[n+1] and the n^{th} scan control line GCL[n].

The data line DL may extend in the y-axis direction. Each of the plurality of data lines DL may be associated with (e.g., connected to) one column. The pixels SP arranged in each of the first to fourth columns COL1, COL2, COL3 and COL4 may receive a data voltage from one data line DL.

The driving voltage line VDL may extend in the y-axis direction. The pixels SP adjacent to each other in the x-axis direction may share one driving voltage line VDL. One driving voltage line VDL may be located between the first and second columns COL1 and COL2 to provide a driving voltage to the 11^{th}, 12^{th}, 21^{st} and 22^{nd} pixels SP11, SP12, SP21 and SP22. Another driving voltage line VDL may be located between the third and fourth columns COL3 and COL4 and may provide a driving voltage to the 13^{th}, 14^{th}, 23^{rd} and 24^{th} pixels SP13, SP14, SP23 and SP24.

The active layers ACTL of the pixels SP in the first and second columns COL1 and COL2 may be symmetrical about the y-axis direction. The source electrode SE1 of the first transistor T1 of the 11^{th} pixel SP11 and the source electrode SE1 of the first transistor T1 of the 12^{th} pixel SP12 may be formed integrally. Accordingly, the pixels SP arranged in the first and second columns COL1 and COL2 may share one driving voltage line VDL, and the source electrode SE1 of the first transistor T1 of each of the 11^{th} pixel SP11 and the 12^{th} pixel SP12 may receive a driving voltage through one driving voltage line VDL.

The active layers ACTL of the pixels SP in the third and fourth columns COL3 and COL4 may be symmetrical about the y-axis direction. The source electrode SE1 of the first transistor T1 of the 13^{th} pixel SP13 and the source electrode SE1 of the first transistor T1 of the 14^{th} pixel SP12 may be formed integrally. Accordingly, the pixels SP arranged in the third and fourth columns COL3 and COL4 may share one driving voltage line VDL, and the source electrode SE1 of the first transistor T1 of each of the 13^{th} pixel SP13 and the 14^{th} pixel SP14 may receive a driving voltage through one driving voltage line VDL. Accordingly, the area of the pixel circuit can be relatively reduced in the display device 10 by relatively reducing the number of the driving voltage lines VDL, so that a high-resolution display device can be implemented.

The active layers ACTL of the pixels SP in the first and second rows CRW1 and CRW2 may be symmetrical about the x-axis direction. The drain electrode DE2 of the second transistor T2 of the 11^{th} pixel SP11 and the drain electrode DE2 of the second transistor T2 of the 21^{st} pixel SP21 may be integrally formed (e.g., as a single component or electrode). The source electrode SE3 of the third transistor T3 of the 11^{th} pixel SP11 and the source electrode SE3 of the third transistor T3 of the 21^{st} pixel SP22 may be formed integrally. The drain electrode DE2 of the second transistor T2 and the source electrode SE3 of the third transistor T3 may correspond to the third node N3 in FIG. 4, and may be connected to the capacitor electrode CPE of the first source metal layer SDL1. The third node N3 of the 11^{th}, pixel SP11 and the third node N3 of the 21^{st} pixel SP21 may be directly connected with each other. The first electrode of the second capacitor C2 of the 11^{th}, pixel SP11 and the first electrode of the second capacitor C2 of the 21^{st} pixel SP21 may be formed integrally. The 11^{th}, pixel SP11 and the 21^{st} pixel SP21 share one capacitor electrode CPE and thus may share one second capacitor C2. By increasing the area of the second capacitor C2, it may be possible to relatively reduce power consumption.

The third node N3 of the 12^{th} pixel SP12 and the third node N3 of the 22^{nd} pixel SP22 may be directly connected with each other. The first electrode of the second capacitor C2 of the 12^{th} pixel SP12 and the first electrode of the second capacitor C2 of the 22^{nd} pixel SP22 may be formed integrally. The 12^{th} pixel SP12 and the 22^{nd} pixel SP22 share one capacitor electrode CPE and thus may share one second capacitor C2.

The initialization voltage line VIL may include a first portion VILa and a second portion VILb. The first portion VILa of the initialization voltage line VIL may be located in the second gate layer GTL2 and extending in the x-axis direction. Each of the first portions VILa of the initialization voltage lines VIL may be associated with one row. The pixels SP located in each of the first and second rows CRW1 and CRW2 may receive an initialization voltage from the first portion VILa of one initialization voltage line VIL.

The second portion VILb of the initialization voltage line VIL may be located in the third source metal layer SDL3 and extending in the y-axis direction, and may be electrically connected to the first portion VILa of the initialization voltage line VIL through a second connection electrode VCE2 of the first source metal layer SDL1. The second portion VILb of one initialization voltage line VIL may be located between adjacent pixels SP in the x-axis direction. For example, the second portion VILb of one initialization voltage line VIL may be located between the second and third columns COL2 and COL3. The second portion VILb of one initialization voltage line VIL may be located between adjacent driving voltage lines VDL in the x-axis direction. The area of the pixel circuit in the display device 10 can be relatively reduced by relatively reducing the number of the initialization voltage lines VIL, so that a high-resolution display device can be implemented.

Referring to FIGS. 8 to 10, the 11^{th}, pixel SP11 may be connected to the n^{th} scan write line GWL[n], the n^{th} scan control line GCL[n], the data line DL, the initialization voltage line VIL, the driving voltage line VDL and the low-level voltage line VSL.

The first transistor T1 may include a semiconductor region ACT1, a source electrode SE1, a drain electrode DE1 and a gate electrode GE1. The semiconductor region ACT1, the source electrode SE1 and the drain electrode DE1 of the first transistor T1 may be located in the active layer ACTL, and the gate electrode GE1 of the first transistor T1 may be located in the first gate layer GTL1. The gate electrode GE1 of the first transistor T1 may overlap with the semiconductor region ACT1 of the first transistor T1. For example, the semiconductor region ACT1 of the first transistor T1 may include low-temperature polycrystalline silicon, and the source electrode SE1 and the drain electrode DE1 of the first transistor T1 may be formed by p-type doping.

The gate electrode GE1 of the first transistor T1 may be electrically connected to the source electrode SE2 of the second transistor T2 through a third electrode C1c of the first capacitor C1 of a third gate layer GTL3. The gate electrode GE1 of the first transistor T1 may be a part of the first electrode C1a of the first capacitor C1, and the second electrode C1b of the first capacitor C1 may be a part of the first portion VILa of the initialization voltage line VIL located in the second gate layer GTL2. The third electrode C1c of the first capacitor C1 may be connected to the first electrode C1a, and the first to third electrodes C1a, C1b and C1c may overlap each other. Accordingly, the first capacitor C1 may have a double-layer structure to ensure the capacity and relatively reduce coupling capacitance between pixel circuits. The first capacitor C1 may initialize the gate electrode GE1 of the first transistor T1 with a voltage equal to an initializing voltage. The source electrode SE1 of the first transistor T1 may be electrically connected to the driving voltage line VDL of the third source metal layer SDL3 through a first connection electrode VCE1 of the first source metal layer SDL1. The drain electrode DE1 of the first transistor T1 may be formed integrally with a drain electrode DE3 of the third transistor T3. The drain electrode DE1 of the first transistor T1 may be electrically connected to a first electrode AE of the light-emitting element ED through a first anode connection electrode ANE1 of the first source metal layer SDL1 and a second anode connection electrode ANE2 of the third source metal layer SDL3.

The second transistor T2 may include a semiconductor region ACT2, a source electrode SE2, a drain electrode DE2 and a gate electrode GE2. The semiconductor region ACT2, the source electrode SE2 and the drain electrode DE2 of the second transistor T2 may be located in the active layer ACTL, and the gate electrode GE2 of the second transistor T2 may be located in the first gate layer GTL1. The gate electrode GE2 of the second transistor T2 may overlap with the semiconductor region ACT2 of the second transistor T2. For example, the semiconductor region ACT2 of the second transistor T2 may include low-temperature polycrystalline silicon, and the source electrode SE3 and the drain electrode DE2 of the second transistor T2 may be formed by p-type doping.

The gate electrode GE2 of the second transistor T2 may be connected to the n^{th} scan write line GWL(n) located in the second gate layer GTL2. The source electrode SE2 of the second transistor T2 may be electrically connected to the gate electrode GE1 of the first transistor T1 through the third electrode C1c of the first capacitor C1. The drain electrode DE2 of the second transistor T2 may be formed integrally with a source electrode SE3 of the third transistor T3. The drain electrode DE2 of the second transistor T2 may be connected to the capacitor electrode CPE of the first source metal layer SDL1. The capacitor electrode CPE may be the first electrode C2a of the second capacitor C2, and the data line DL may be located in the second source metal layer SDL2 and may include the second electrode C2b of the second capacitor C2. The second capacitor C2 may change the drain electrode DE2 of the second transistor T2 and the source electrode SE3 of the third transistor T3 with a voltage equal to the data voltage. The first electrode C2a of the second capacitor C2 of the 11^{th} pixel SP11 and the first electrode C2a of the second capacitor C2 of the 21^{st} pixel SP21 may be formed integrally. The 11^{th} pixel SP11 and the 21^{st} pixel SP21 share one capacitor electrode CPE and thus may share one second capacitor C2. By increasing the area of the second capacitor C2, it may be possible to relatively reduce power consumption.

The third transistor T3 may include a semiconductor region ACT3, a source electrode SE3, a drain electrode DE3 and a gate electrode GE3. The semiconductor region ACT3, the source electrode SE3 and the drain electrode DE3 of the third transistor T3 may be located in the active layer ACTL, and the gate electrode GE3 of the third transistor T3 may be located in the first gate layer GTL1. The gate electrode GE3 of the third transistor T3 may overlap with the semiconductor region ACT3 of the third transistor T3. For example, the semiconductor region ACT3 of the third transistor T3 may include low-temperature polycrystalline silicon, and the source electrode SE3 and the drain electrode DE3 of the third transistor T3 may be formed by p-type doping.

The gate electrode GE3 of the third transistor T3 may be connected to the n^{th} scan control line GCL(n) located in the second gate layer GTL2 to receive the n^{th} scan control signal. The source electrode SE3 of the third transistor T3 may be formed integrally with the drain electrode DE2 of the second transistor T2. The source electrode SE3 of the third transistor T3 may be connected to the capacitor electrode CPE. The drain electrode DE3 of the third transistor T3 may be formed integrally with the drain electrode DE1 of the first transistor T1. The drain electrode DE3 of the third transistor T3 may be electrically connected to the first electrode AE of the light-emitting element ED through the first and second anode connection electrodes ANE1 and ANE2.

The first capacitor C1 may include the first to third electrodes C1a, C1b and C1c. The first to third electrodes C1a, C1b and C1c of the first capacitor C1 may overlap each other. The first electrode C1a of the first capacitor C1 may be located in the first gate layer GTL1, the second electrode C1b may be located in the second gate layer GTL2, and the third electrode C1c may be located in the third gate layer GTL3. The first electrode C1a of the first capacitor C1 may include the gate electrode GE1 of the first transistor T1, and the second electrode C1b may be a part of the first portion VILa of the initialization voltage line VIL. The third electrode C1c of the first capacitor C1 may be connected to the first electrode C1a. Accordingly, the first capacitor C1 may have a double-layer structure and may maintain a potential difference between the gate electrode GE1 of the first transistor T1 and the initialization voltage line VIL.

The second capacitor C2 may include the first electrode C2a and the second electrode C2b. The first and second electrodes C2a and C2b of the second capacitor C2 may overlap each other. The first electrode C2a of the second capacitor C2 may be located in the first source metal layer SDL1, and the second electrode C2b may be located in the second source metal layer SDL2. The first electrode C2a of the second capacitor C2 may be a capacitor electrode CPE, and the second electrode C2b of the second capacitor C2 may be a part of the data line DL. Accordingly, the second capacitor C2 may maintain a potential difference between the drain electrode DE2 of the second transistor T2 and the data line DL.

In FIG. 11, the display device 10 may include a substrate SUB, an active layer ACTL, a first gate insulator G11, a first gate layer GTL1, a second gate insulator G12, a second gate layer GTL2, a third gate insulator G13, a third gate layer GTL3, an interlayer dielectric layer ILD, a first source metal layer SDL1, a first via layer VIA1, a second source metal layer SDL2, a second via layer VIA2, a third source metal layer SDL3, a third via layer VIA3, a pixel-defining layer PDL, a light-emitting element ED, and an encapsulation layer TFEL.

The substrate SUB may be a base substrate or a base member. The substrate SUB may be a flexible substrate that can be bent, folded, or rolled. For example, the substrate SUB may include a glass material, but the constituent material of the substrate SUB is not limited thereto. As another example, the substrate SUB may include a polymer resin such as polyimide PI.

The active layer ACTL may be located on the substrate SUB. The active layer ACTL may include an silicon-based material. The active layer ACTL may include the semiconductor regions ACT1, ACT2 and ACT3, the source electrodes SE1, SE2 and SE3, and the drain electrodes DE1, DE2 and DE3 of the first to third transistors T1, T2 and T3, respectively.

The first gate insulator G11 may be located on the active layer ACTL. The first gate insulator G11 may insulate the active layer ACTL from the first gate layer GTL1.

The first gate layer GTL1 may be located on the first gate insulator G11. The first gate layer GTL1 may include the gate electrodes GE1, GE2 and GE3 of the first to third transistors T1, T2 and T3, respectively.

The second gate insulator G12 may be located on the first gate layer GTL1. The second gate insulator G12 may insulate the first gate layer GTL1 from the second gate layer GTL2.

The second gate layer GTL2 may be located on the second gate insulator G12. The second gate layer GTL2 may include the n^{th} scan write line GWL[n], the n^{th} scan control line GCL[n], and the first portion VILa of the initialization voltage line VIL.

The third gate insulator G13 may be located on the second gate layer GTL2. The third gate insulator G13 may insulate the second gate layer GTL2 from the third gate layer GTL3.

The third gate layer GTL3 may be located on the third gate insulator G13. The third gate layer GTL3 may include the third electrode C1c of the first capacitor C1.

The interlayer dielectric layer ILD may be located on the third gate layer GTL3. The interlayer dielectric layer ILD may insulate the third gate layer GTL3 from the first source metal layer SDL1.

The first source metal layer SDL1 may be located on the interlayer dielectric layer ILD. The first source metal layer SDL1 may include the first connection electrode VCE1, the first anode connection electrode ANE1, and the capacitor electrode CPE.

The first via layer VIA1 may be located on the first source metal layer SDL1. The first via layer VIA1 may insulate the first source metal layer SDL1 from the second source metal layer SDL2.

The second source metal layer SDL2 may be located on the first via layer VIA1. The second source metal layer SDL2 may include a data line DL.

The second via layer VIA2 may be located on the second source metal layer SDL2. The second via layer VIA2 may insulate the second source metal layer SDL2 from the third source metal layer SDL3.

The third source metal layer SDL3 may be located on the second via layer VIA2. The third source metal layer SDL3 may include the driving voltage line VDL and the second anode connection electrode ANE2.

The third via layer VIA3 may be located on the third source metal layer SDL3. The third via layer VIA3 may insulate the third source metal layer SDL3 from the first electrode AE of the light-emitting element ED.

The emission material layer EDL may include a pixel-defining layer PDL and light-emitting elements ED. The light-emitting element ED may include a first electrode AE, an emissive layer EL, and a second electrode CAT.

The pixel-defining layer PDL may be located on the third via layer VIA3. The pixel-defining layer PDL may define a plurality of emission areas EA. The pixel-defining layer PDL may include an organic insulating material such as polyimide (PI).

The first electrode AE may be located on the third via layer VIA3. The first electrode AE may overlap with one of the plurality of emission areas EA defined by the pixel-defining layer PDL. The first electrode AE may receive a driving current from the pixel circuit of the pixel SP through the first and second anode connection electrodes ANE1 and ANE2.

The emissive layer EL may be located on the first electrode AE. For example, the emissive layer EL may be, but is not limited to, an organic emissive layer made of an organic material. If the emissive layer EL is an organic light-emitting layer, when the pixel circuit of the pixel SP applies a voltage (e.g., a set or predetermined voltage) to the first electrode AE and the second electrode CAT receives a common voltage or cathode voltage, holes may move to the organic light-emitting layer EL through a hole transporting layer and electrons may move to the organic light-emitting layer EL through a hole transporting layer, and they combine in the organic light-emitting layer EL to emit light.

The second electrode CAT may be located on the emissive layer EL. For example, the second electrode CAT may be implemented in the form of a common electrode extending across all of the pixels SP, instead of being arranged separately in each of the pixels SP. The second electrode CAT may be located on the emissive layer EL in the emission areas EA and may be located on the pixel-defining layer PDL except for the emission areas EA.

The encapsulation layer TFEL may be located on the second electrode CAT to cover the light-emitting diodes ED. The encapsulation layer TFEL may include at least one inorganic film to prevent or reduce permeation of contaminants such as oxygen or moisture into the light-emitting elements ED. The encapsulation layer TFEL may include at least one organic film to protect the light-emitting elements ED from particles such as dust.

It should be understood, however, that the aspects and features of embodiments of the present disclosure are not restricted to those specifically described and illustrated herein. The above and other aspects of the present disclosure will become more apparent to one of ordinary skill in the art to which the present disclosure pertains by referencing the claims, with equivalents thereof to be included therein.

What is claimed is:

1. A display device comprising:
a first pixel in a first row and a first column; and
a second pixel in a second row next to the first row and in the first column,
wherein each of the first and second pixels comprises:
a light-emitting element on a substrate;
a first transistor configured to supply a driving current to a second node which is connected to a first electrode of the light-emitting element, based on a voltage of a first node which is connected to a gate electrode of the first transistor;
a second transistor connected to the first node; and
a third transistor connected between a third node which is connected to a drain electrode of the second transistor and the second node, and
wherein the third node of the first pixel and the third node of the second pixel are directly connected with each other.

2. The display device of claim 1, further comprising:
an initialization voltage line configured to supply an initialization voltage; and
a data line configured to supply a data voltage,
wherein each of the first and second pixels comprises:
a first capacitor connected between the first node and the initialization voltage line; and
a second capacitor connected between the third node and the data line.

3. The display device of claim 2, wherein a first electrode of the second capacitor of the first pixel and a first electrode of the second capacitor of the second pixel are integrally formed.

4. The display device of claim 3, wherein the drain electrode of the second transistor of the first pixel and the drain electrode of the second transistor of the second pixel are formed integrally.

5. The display device of claim 2, wherein each of the first and second pixels comprises:
an active layer on the substrate and comprising a semiconductor region of each of the first to third transistors;
a first gate layer on the active layer and comprising a first electrode of the first capacitor;
a second gate layer on the first gate layer and comprising a second electrode of the first capacitor;
a first source metal layer on the second gate layer and comprising a capacitor electrode which is connected to the first electrode of the second capacitor; and
a second source metal layer on the first source metal layer and comprising the data line which is connected to the second electrode of the second capacitor.

6. The display device of claim 5, wherein a capacitor electrode of the first pixel and the capacitor electrode of the second pixel are integrally formed.

7. The display device of claim 5, wherein a first portion of the initialization voltage line is in the second gate layer and extends in a first direction, and a second portion of the initialization voltage line is in a third source metal layer on the second source metal layer and extends in a second direction intersecting the first direction.

8. The display device of claim 1, further comprising:
a third pixel in the first row and a second column next to the first column; and
a fourth pixel in the second row and in the second column,
wherein each of the third and fourth pixels comprises:
a light-emitting element on a substrate;
a first transistor configured to supply a driving current to a second node which is connected to a first electrode of the light-emitting element, based on a voltage of a first node which is connected to a gate electrode;
a second transistor connected to the first node; and
a third transistor connected between a third node which is connected to a drain electrode of the second transistor and the second node, and
wherein the third node of the third pixel and the third node of the fourth pixel are directly connected with each other.

9. The display device of claim 8, wherein a source electrode of the first transistor of the first pixel and a source electrode of the first transistor of the third pixel are formed integrally.

10. The display device of claim 8, wherein each of the first and second pixels comprises:
an active layer on the substrate;
a first gate layer on the active layer;
a second gate layer on the first gate layer;
a first source metal layer on the second gate layer;
a second source metal layer on the first source metal layer; and
a third source metal layer comprising a driving voltage line on the second source metal layer, and
wherein a source electrode of the first transistor of the first pixel and a source electrode of the first transistor of the third pixel share a single driving voltage line.

11. A display device comprising:
a first pixel in a first row and a first column;
a second pixel in a second row next to the first row and the first column;
an initialization voltage line configured to supply an initialization voltage; and
a data line configured to supply a data voltage,
wherein each of the first and second pixels comprises:
a light-emitting element on a substrate;
a first transistor configured to supply a driving current to a second node which is connected to a first electrode of the light-emitting element, based on a voltage of a first node which is connected to a gate electrode;
a first capacitor connected between the first node and the initialization voltage line;
a second transistor connected to the first node;
a second capacitor connected between the data line and a third node which is connected to a drain electrode of the second transistor; and
a third transistor electrically connecting the third node with the second node, and
wherein a first electrode of the second capacitor of the first pixel and a first electrode of the second capacitor of the second pixel are formed integrally.

12. The display device of claim 11, further comprising:
a first scan write line configured to supply a first scan write signal to the second transistor of the first pixel;
a second scan write line configured to supply a second scan write signal to the second transistor of the second pixel; and
a scan control line configured to supply a scan control signal to the third transistor of the first pixel and the third transistor of the second pixel.

13. The display device of claim 11, wherein each of the first and second pixels comprises:
an active layer on the substrate;
a first gate layer on the active layer and comprising a first electrode of the first capacitor;
a second gate layer on the first gate layer and comprising a second electrode of the first capacitor;
a first source metal layer on the second gate layer and comprising a capacitor electrode which is connected to the first electrode of the second capacitor; and
a second source metal layer on the first source metal layer and comprising the data line which is connected to the second electrode of the second capacitor.

14. The display device of claim 13, wherein each of the first and second pixels further comprises a third gate layer between the second gate layer and the first source metal layer, and
wherein a third electrode of the first capacitor is in the third gate layer and connected to the first electrode of the first capacitor.

15. The display device of claim 14, wherein the third electrode of the first capacitor electrically connects the first electrode of the first capacitor with a source electrode of the second transistor.

16. The display device of claim 13, wherein the active layer of the first pixel and the active layer of the second pixel are symmetrical with respect to a boundary line between the first pixel and the second pixel.

17. The display device of claim 13, wherein a first portion of the initialization voltage line is in the second gate layer and extends in a first direction, and a second portion of the initialization voltage line is in a third source metal layer on the second source metal layer and extends in a second direction intersecting the first direction.

18. The display device of claim 17, wherein the first portion of the initialization voltage line comprises the second electrode of the first capacitor.

19. The display device of claim 13, further comprising:
a third pixel in the first row and a second column next to the first column; and
a fourth pixel in the second row and the second column,
wherein each of the third and fourth pixels comprises:
an active layer on the substrate and comprising a semiconductor region of each of the first to third transistors;
a first gate layer on the active layer and comprising a first electrode of the first capacitor;
a second gate layer on the first gate layer and comprising a second electrode of the first capacitor;
a first source metal layer on the second gate layer and comprising a capacitor electrode which is connected to the first electrode of the second capacitor; and
a second source metal layer on the first source metal layer and comprising the data line which is connected to the second electrode of the second capacitor, and
wherein the active layer of the first pixel and the active layer of the third pixel are symmetrical with respect to a boundary line between the first pixel and the third pixel.

20. The display device of claim 19, wherein each of the third and fourth pixels comprises:
a light-emitting element on a substrate;
a first transistor configured to supply a driving current to a second node which is connected to a first electrode of the light-emitting element, based on a voltage of a first node which is connected to a gate electrode;
a second transistor connected to the first node; and
a third transistor connected between a third node which is connected to the drain electrode of the second transistor and the second node, and
wherein a source electrode of the first transistor of the first pixel and a source electrode of the first transistor of the third pixel share a single driving voltage line.
